(19) United States
(12) Patent Application Publication
(10) Pub. No.: US 2009/0316332 A1
(43) Pub. Date: Dec. 24, 2009

(54) SEMICONDUCTOR DEVICE CONTAINING THIN FILM CAPACITOR AND MANUFACTURE METHOD FOR THIN FILM CAPACITOR

(75) Inventors: Kazuya OKUBO, Kawasaki (JP); Shinichi AKIYAMA, Kawasaki (JP); Kenji NAITO, Kawasaki (JP); Makoto NAKAMURA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/366,015

(22) Filed: Feb. 5, 2009

(30) Foreign Application Priority Data
Jun. 18, 2008 (JP) 2008-159093

(51) Int. Cl. H01G 4/06; H01G 9/00

(52) U.S. Cl. 361/311; 29/25.03; 257/532

(57) ABSTRACT

A thin film capacitor is disposed over a semiconductor substrate. The thin film capacitor includes a lower electrode at least an upper surface of which is made of amorphous or microcrystalline metal, a dielectric film disposed over the lower electrode, and an upper electrode disposed over the dielectric film.

### CROSS-REFERENCE TO RELATED APPLICATION

This application is based upon and claims the benefit of priority of the prior Japanese Patent Application No. 2008-159093, filed on Jun. 18, 2008, the entire contents of which are incorporated herein by reference.

### FIELD

The embodiments discussed herein are related to a semiconductor device having a thin film capacitor formed over a substrate and to a manufacture method for a thin film capacitor.

### BACKGROUND

A metal/insulator/metal (MIM) structure is now being adopted to a capacitor for a high frequency device and a capacitor for decoupling. When an electrode is made of metal, an electrode resistance can be reduced and electrode depletion can be prevented as compared to using polycrystalline silicon. TiN is widely used as the material of upper and lower electrodes of a MIM capacitor, from the viewpoint of electrical characteristics and workability. However, since a TiN film is usually polycrystalline having a columnar structure, a surface roughness is likely to become large. If the roughness of a lower electrode surface becomes large, an electric field is locally concentrated so that dielectric breakdown is likely to occur and a leak current increases.

The surface of a TiN film can be planarized by performing chemical mechanical polishing after the TiN film is deposited or by sputtering a surface layer with Ar (Japanese Laid-open Patent Publication No. 2002-203915). A surface roughness can be alleviated by depositing a Ta film on the TiN film (Japanese Laid-open Patent Publication No. 2007-305654). Researches on TiN application to a thin film resistor element are reported (N. D. Cuong et al., “Effects of Nitrogen Concentration on Structural and Electrical Properties of Titanium Nitride for Thin-Film Resistor Applications”, Electrochemical and Solid-State Letters, 9(9) G279-G281(2006)), and researches on a growth mechanism of TiN are also reported (T. Q. Li et al., “Initial growth and texture formation during reactive magnetron sputtering of TiN on Si(111)”, J. Vac. Sci. technol. A20(3) pp. 583-588, May/June 2002).

### SUMMARY

A semiconductor device includes: a semiconductor substrate; and a thin film capacitor disposed over the semiconductor substrate, the thin film capacitor including a lower electrode at least a surface layer of which is made of amorphous or microcrystalline metal, a dielectric film disposed over the lower electrode, and an upper electrode disposed over the dielectric film.

The object and advantages of the invention will be realized and attained by means of the elements and combination particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A to 1G are cross sectional views of a semiconductor device during manufacture of an embodiment, and FIG. 1H is a cross sectional view of the semiconductor device of the embodiment.

FIGS. 2A to 2F are SEM photographs of samples A to F forming a TiN film or a Ti film at different partial pressures of Ar and N₂ of sputtering gas.

FIG. 3 is a graph illustrating measurement results of an arithmetic mean roughness and a root mean square roughness of the TiN films and Ti film of samples A to F.

FIG. 4 is a graph illustrating X-ray diffraction patterns of samples A to F.

FIG. 5 is a graph illustrating measurement results of resistivities of the TiN films and Ti film of samples A to F.

FIG. 6 is a graph illustrating measurement results of an element concentration in a TiN film of each of samples having the TiN film formed under conditions of different nitrogen partial pressures of sputtering gas.

FIG. 7A is a graph illustrating measurement results of TDDB characteristics of three samples having MIM capacitor structures, and FIGS. 7B to 7D are cross sectional views of the three samples.

FIG. 8A is a graph illustrating breakdown voltage test results of two samples having MIM capacitor structures, and FIG. 8B is a cross sectional view of the sample measured.

FIG. 9 is a graph illustrating X-ray diffraction patterns of three samples having different TiN film thicknesses and a sample having a Ti film.

### DESCRIPTION OF EMBODIMENTS

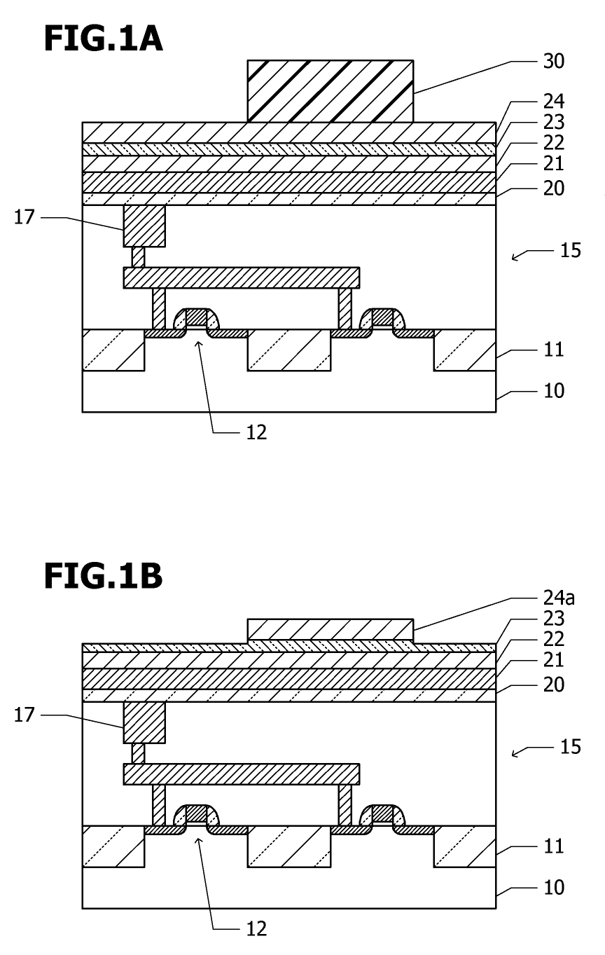

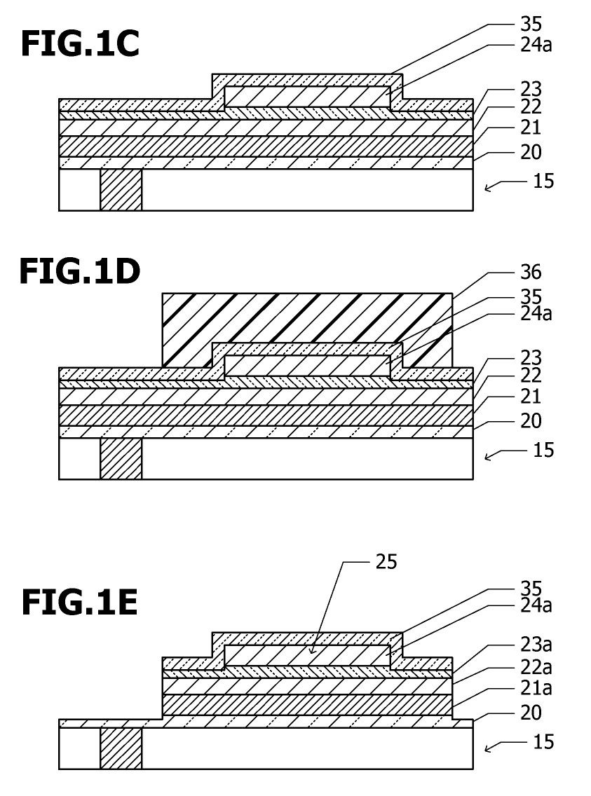

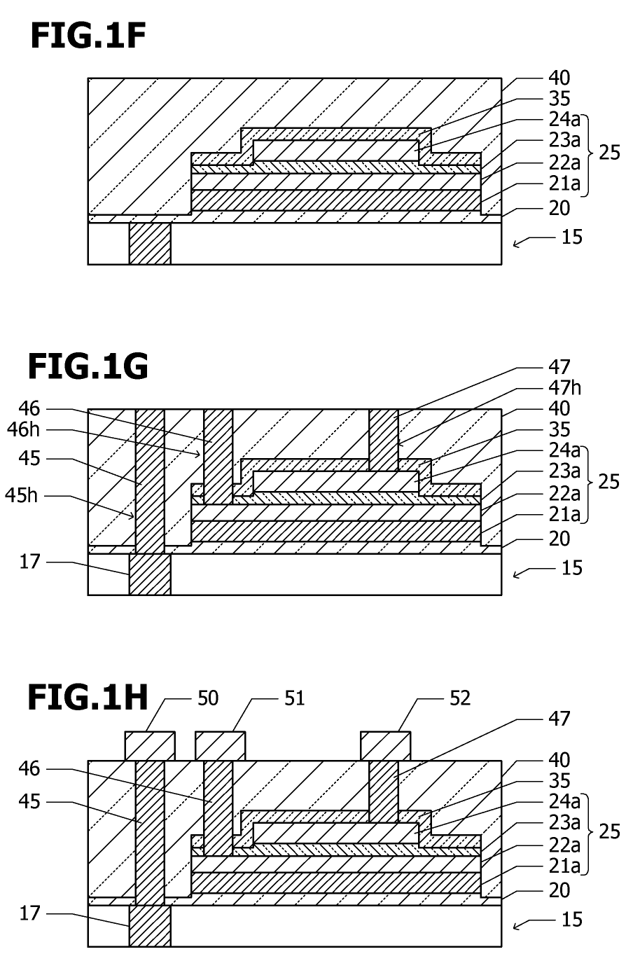

With reference to FIGS. 1A to 1H, description will be made on a manufacture method for a semiconductor device according to an embodiment.

As illustrated in FIG. 1A, an element isolation insulating film 11 is formed in the surface layer of a semiconductor substrate 10 of silicon or the like to define active regions. A MOS transistor 12 is formed in the active region. A multilevel interconnection layer 15 is formed on the semiconductor substrate 10. The MOS transistor 12 is connected to a wiring 17 in the uppermost layer in the multilevel interconnection layer 15 via plugs and wirings in the multilevel interconnection layer 15. The element isolation insulating film 11, MOS transistor 12 and multilevel interconnection layer 15 are formed by well-known techniques such as photolithography, etching, film formation and chemical mechanical polishing.

A silicon oxide film 20 having a thickness of 100 nm is formed on the multilevel interconnection layer 15 by chemical vapor deposition (CVD). A first lower electrode film 21 having a thickness of 150 nm and made of Al is formed on the silicon oxide film 20 by sputtering. A second lower electrode film 22 having a thickness of 50 nm and made of amorphous or microcrystalline TiN is formed on the first lower electrode film 21 by sputtering. The film forming conditions of the second lower electrode film 22 are, for example, as follows:
Sputtering system: DC magnetron sputtering system
Target: metallic titanium
Sputtering gas: mixture gas of Ar and N₂
Gas flow rate: Ar: 100 sccm, N₂: 20 sccm
Chamber inner pressure: 0.47 Pa (3.5 mTorr)
Substrate temperature: room temperature
DC power: 3000 W
Film formation time: 20 sec

A dielectric film 23 having a thickness of 40 nm and made of SiN is formed on the second lower electrode film 22 by CVD. An upper electrode film 24 having a thickness of 100 nm and made of TiN is formed on the dielectric film 23 by sputtering.

A resist pattern 30 is formed on the upper electrode film 24. By using the resist pattern 30 as an etching mask, the upper electrode film 24 is etched. For this etching, dry etching is applicable using chlorine-based gas such as Cl₂ at a flow rate of 60 sccm and BCl₂ at a flow rate of 80 sccm. After the upper electrode film 24 is etched, the resist pattern 30 is removed.

As illustrated in FIG. 1B, an upper electrode 24a of TiN remains in the area where the resist pattern 30 was formed. In this process, a surface layer of the dielectric film 23 is also etched thinly.

As illustrated in FIG. 1C, a cover film 35 having a thickness of 70 nm and made of SiC is formed on the dielectric film 23 and upper electrode 24a. In FIG. 1C and succeeding Figures, the substrate 10 and a portion of the multilevel interconnection layer 15 on the substrate side are omitted. The cover film 35 may be formed by chemical vapor deposition (CVD).

As illustrated in FIG. 1D, a resist pattern 36 is formed on the cover film 35. The resist pattern 36 includes the upper electrode 24a inside itself as viewed in plan.

By using the resist pattern 36 as an etching mask, the layers from the cover film 35 to the first lower electrode 21 are etched. This etching may be performed under the same conditions as those for etching the upper electrode film 24. After the etching, the resist pattern 36 is removed.

As illustrated in FIG. 1E, left in the area where the resist pattern 36 was formed are a cover film 35a of SiC, a first lower electrode 21a of Al, a second lower electrode 22a of amorphous or microcrystalline TiN, and a dielectric film 23a of SiN. In this process, the surface layer of the silicon oxide film 20 in the area not covered with the resist pattern 36 is also etched thinly. A MIM capacitor 25 is constituted of the first lower electrode 21a, second lower electrode 22a, dielectric film 23a, and upper electrode 24a.

As illustrated in FIG. 1F, an interlayer insulating film 40 having a thickness of 1200 nm and made of silicon oxide is formed on the MIM capacitor 25 and silicon oxide film 20, and the surface of the interlayer insulating film 40 is planarized by chemical mechanical polishing (CMP).

As illustrated in FIG. 1G, via holes 45h, 46h and 47h are formed. The via hole 45h penetrates the interlayer insulating film 40 and silicon oxide film 20, and reaches the wiring 17. The via hole 46h is disposed at the side of the upper electrode 24a, penetrates the interlayer insulating film 40, cover film 35,and dielectric film 23a, and reaches the second lower electrode 22a. The via hole 47h penetrates the interlayer insulating film 40 and cover film 35, and reaches the upper electrode 24a.

The via holes 45h, 46h and 47h are filled with conductive plugs 45, 46 and 47, respectively. Each of these conductive plugs 45 to 47 is formed by sequentially depositing a TiN film of 50 nm in thickness and a tungsten (W) film of 300 nm in thickness, and thereafter removing unnecessary portions by CMR The conductive plug 45 is connected to the wiring 17 in the uppermost layer of the multilevel interconnection layer 15. The conductive plugs 46 and 47 are connected to the second lower electrode 22a and upper electrode 24a of the MIM capacitor 25, respectively.

As illustrated in FIG. 1H, wirings 50, 51 and 52 of Al are formed on the interlayer insulating film 40. The wirings 50, 51 and 52 are connected to the conductive plugs 45, 46 and 47, respectively. For example, the wiring 51 is a power source wiring, and the wiring 52 is a ground wiring. The MIM capacitor 25 is therefore connected between the power source wiring and ground wiring.

Next, description will be made of the film forming conditions for the second lower electrode film 23 of TiN, and the surface roughness of the film.

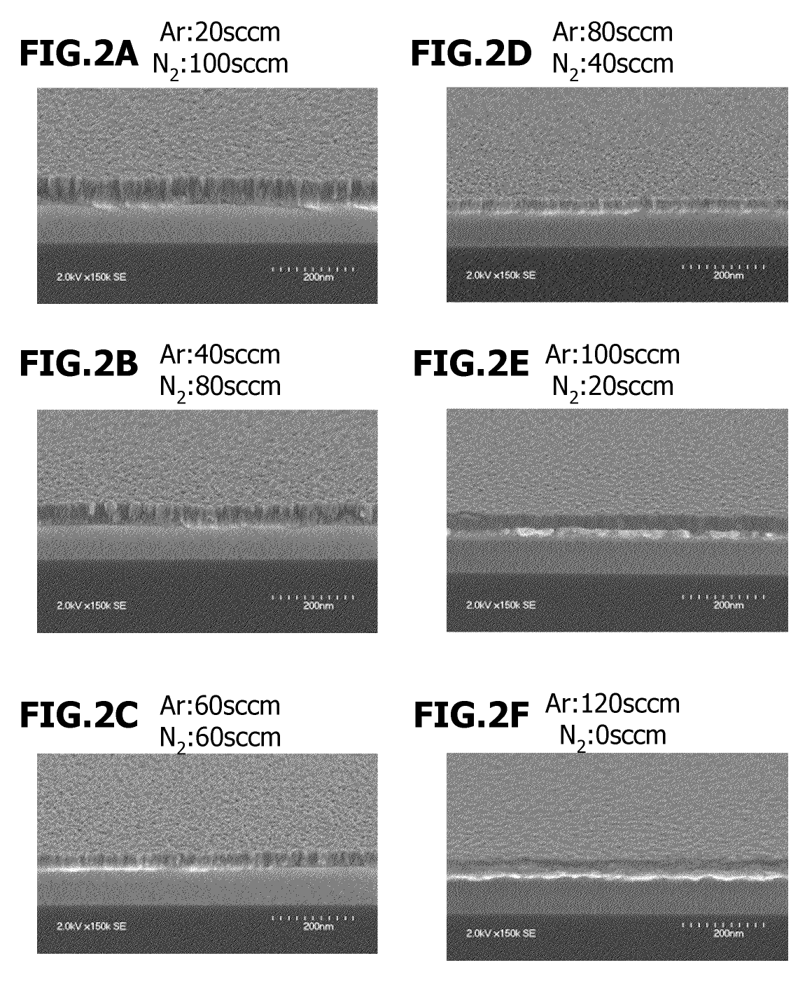

FIGS. 2A to 2F are SEM photographs of samples A to F, which have, on a SiO₂ film, a TiN film or a Ti film formed by changing a composition ratio of sputtering gas. (Ar flow rates, N₂ flow rates) when TiN films of samples A to F are formed are (20 sccm, 100 sccm), (40 sccm, 80 sccm), (60 sccm, 60 sccm), (80 sccm, 40 sccm), (100 sccm, 20 sccm), and (120 sccm, 0 sccm), respectively.

The columnar structure is observed in samples A to D, but is not observed in samples E and F. It can be seen that if a nitrogen concentration of sputtering gas is high, the TiN film has the columnar structure, and as the nitrogen concentration becomes lower, the columnar structure changes to a grain structure.

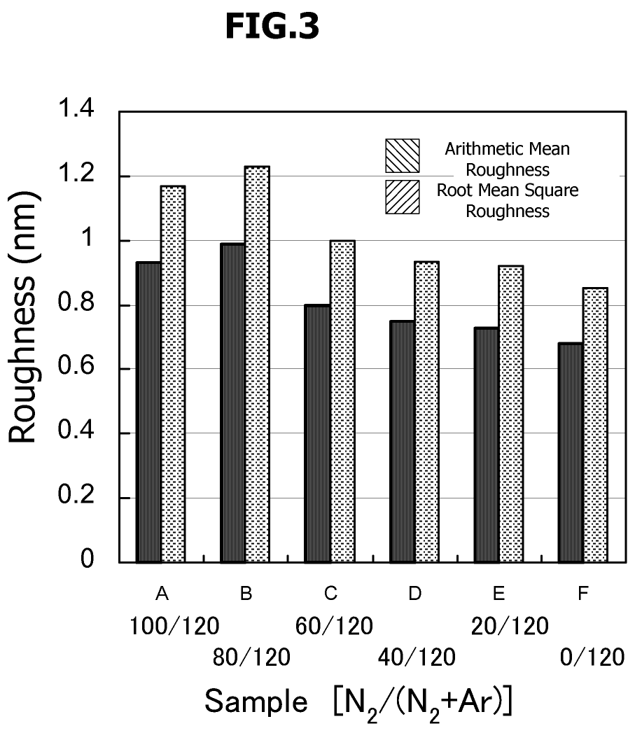

FIG. 3 illustrates the measurement results of an arithmetic mean roughness and a root mean square roughness of the surfaces of the TiN and Ti films of samples A to F. The abscissa represents samples A to F, and the ordinate represents a roughness in the unit of“nm” It can be seen that as a relative flow rate of nitrogen gas is reduced, the roughness is reduced. Reduction in the surface roughness results from a change in crystalline structure from the columnar structure to the grain structure of the TiN film.

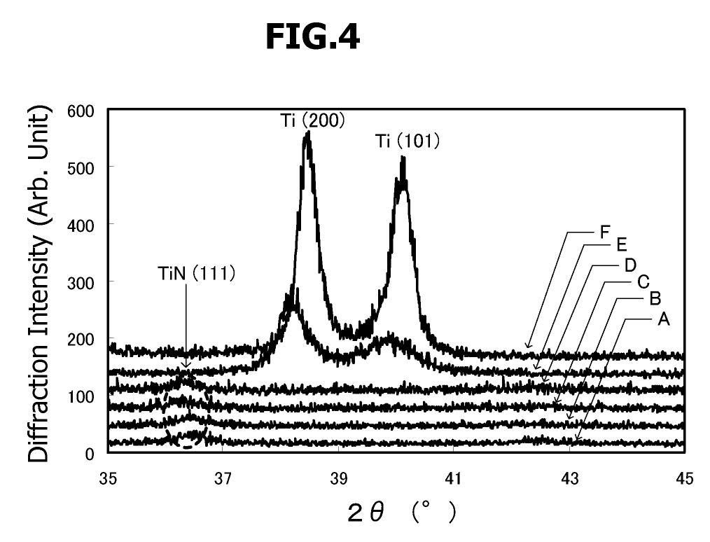

FIG. 4 illustrates X-ray diffraction patterns of the TiN and Ti films of samples A to F. In samples A to D, an elevation (broad peak) caused by the TiN (111) plane is observed near at 36.5°. The film of sample F is a Ti film. Therefore, an elevation to be caused by the TiN (111) plane is not observed, but sharp peaks caused by the Ti (200) and (101) planes are observed.

In contrast, in sample E, an elevation to be caused by the TiN (111) plane is not observed, but rather broad peaks are observed near the peaks caused by the Ti (200) and (101) planes. A shift of peaks of the X-ray diffraction pattern of sample E toward the lower angle side from the peak positions of the Ti (200) and (101) planes results from that since N is contained in Ti, a lattice constant changes from that of pure Ti. Further, since an elevation to be caused by the TiN (111) plane is not observed, it can be seen that large crystalline grains of TiN are not formed. It can be seen from these analysis results that the Ti film of sample E is amorphous or microcrystalline.

The term “TiN” herein used does not mean that a composition ratio of Ti to N is 1:1, but means that “TiN” is substance mainly containing Ti and N. The term “amorphous or microcrystalline TiN” herein used means TiN whose X-ray diffraction pattern does not have a peak or elevation to be caused by the TiN (111) plane.

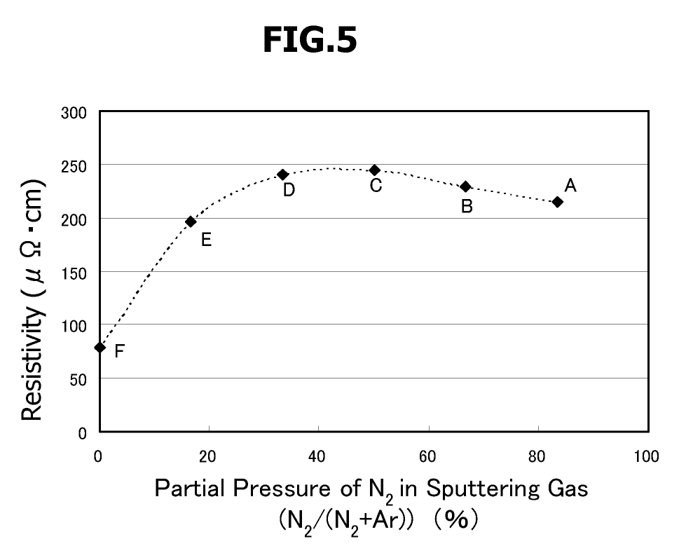

FIG. 5 illustrates resistivities of the TiN or Ti films of samples A to F. The abscissa represents a partial pressure of N₂ gas in sputtering gas in the unit of“%”, and the ordinate represents a resistivity in the unit of ““μΩ·cm”” For the TiN films of samples A to D manufactured under the condition that a partial pressure of N₂ gas in sputtering gas is equal to or higher than 33%, the resistivity is equal to or higher than 220 μΩ·cm. In contrast, for the TiN film of sample E manufactured under the condition that a partial pressure of N₂ gas in sputtering gas is 17%, the resistivity is 200 μΩ·cm which is an intermediate value between the resistivity of the Ti film of sample F and the resistivity of each of the Ti films of samples A to D.

It can be inferred from this evaluation result that the Ti films of samples A to D have the columnar structure. The measurement results of resistivities are consistent with the X-ray diffraction results indicating that the TiN film of sample E is not polycrystal of the columnar structure but has a structure approximate to that of Ti.

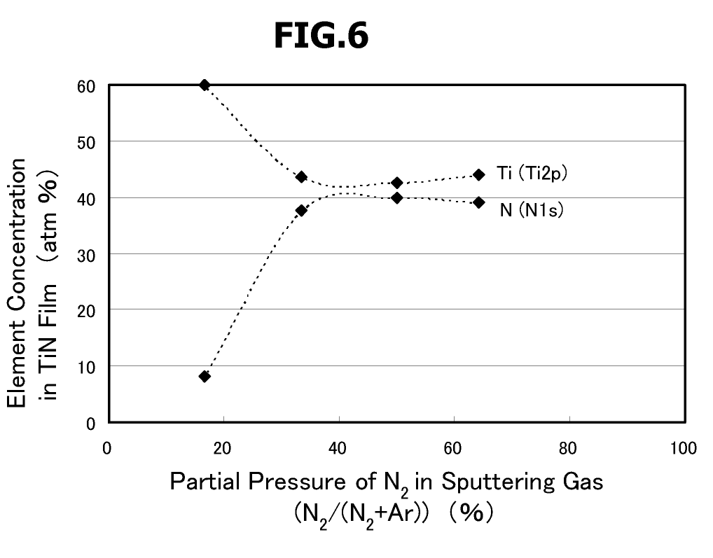

FIG. 6 illustrates measurement results of an element concentration of TiN films formed by varying a partial pressure of nitrogen gas in sputtering gas. The abscissa represents a partial pressure of nitrogen gas in sputtering gas in the unit of “%”, and the ordinate represents an element concentration in the unit of “atm %”. The element concentration is calculated by obtaining an area intensity of a peak caused by each element by XPS analysis and using a sensitivity coefficient recommended by Physical Electronics, Inc.

It can be understood that a concentration ratio of Ti to N is approximately 1:1 at a nitrogen gas partial pressure equal to or higher than 33%, and that TiN having a composition ratio near the stoichiometric composition ratio is formed. This measurement results are consistent with the X-ray diffraction pattern evaluation results and resistivity evaluation results. At a nitrogen gas partial pressure of 17%, the N concentration lowers to about 8 atom %. It can be considered that TiN crystal having the columnar structure is not formed because the amount of nitrogen is small as compared to the stoichiometric composition ratio.

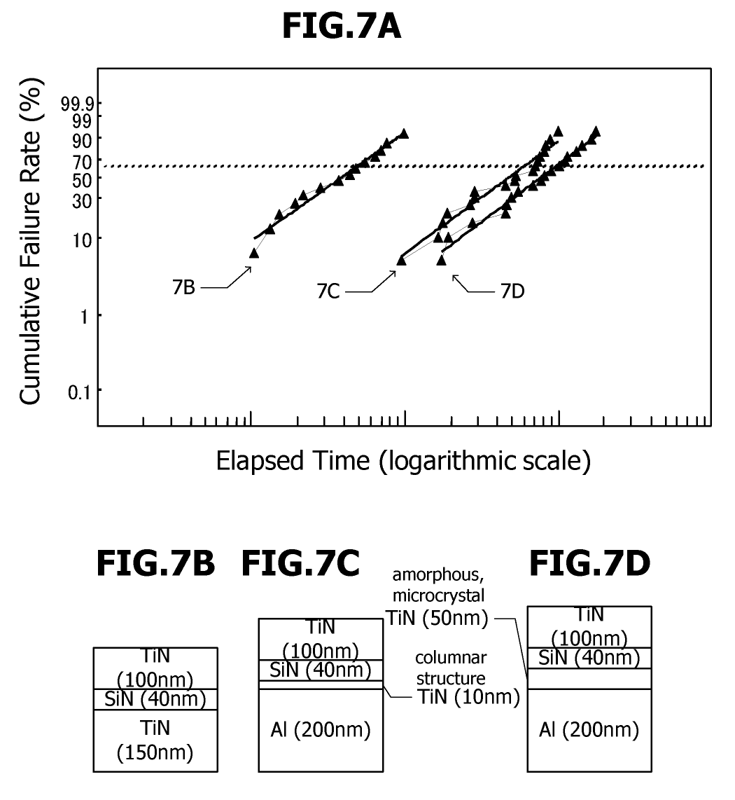

FIG. 7A illustrates TDDB test results of three types of samples having the MIM capacitor structure. The abscissa represents an elapsed time in a logarithmic scale, and the ordinate represents a cumulative failure rate in the unit of “%”.

FIGS. 7B to 7D illustrate cross sectional structures of the three samples. In all samples, a dielectric film is a SiN film having a thickness of 40 nm, and an upper electrode is a TiN film having a thickness of 100 nm. A lower electrode of the sample illustrated in FIG. 7B is a polycrystalline TiN film of the columnar structure having a thickness of 150 nm. A lower electrode of the sample illustrated in FIG. 7C has a two-layer structure of an Al film having a thickness of 200 nm and a polycrystalline TiN film of the columnar structure having a thickness of 10 nm. A lower electrode of the sample illustrated in FIG. 7D has a two-layer structure of an Al film having a thickness of 200 nm and an amorphous or microcrystalline TiN film having a thickness of 50 nm.

The measurement results represented by symbols 7B to 7D illustrated in FIG. 7A are for the samples illustrated in FIGS. 7B to 7D, respectively. It can be understood from the measurement results of the samples illustrated in FIGS. 7B and 7C that a lifetime can be prolonged by about one digit by thinning the TiN film to 10 nm. This can be considered that as the TiN film is thinned, growth of columnar crystal grains is suppressed and a surface roughness of the TiN film is reduced.

As the TiN film of the lower electrode is amorphous or microcrystalline as in the case of the sample illustrated in FIG. 7D, a lifetime equal to or longer than that of the sample illustrated in FIG. 7C can be obtained even if the TiN film has the thickness of 50 nm. The reason for this is that as the TiN film of the lower electrode is amorphous or microcrystalline, the surface roughness is reduced.

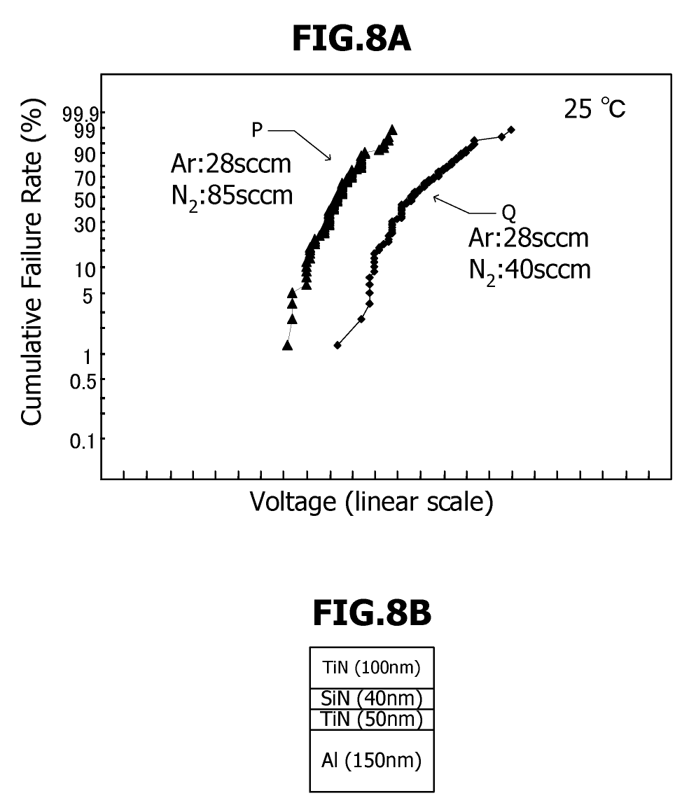

FIG. 8A illustrates breakdown voltage measurement results of two samples P and Q having the MIM capacitor structure. The abscissa represents an applied voltage in a linear scale, and the ordinate represents a cumulative failure rate in the unit of “%”.

FIG. 8B illustrates the cross sectional structure of samples P and Q. A lower electrode has a two-layer structure of an Al film having a thickness of 150 nm and a TiN film having a thickness of 50 nm. A dielectric film is constituted of a SiN film having a thickness of 40 nm. An upper electrode is constituted of a TiN film having a thickness of 100 nm. For sample P, the flow rates of Ar and N₂ of sputtering gas used when the TiN film of the lower electrode is formed are set to 28 sccm and 85 sccm, respectively. Namely, a partial pressure ratio of nitrogen gas is about 75%. For sample P, the flow rates of Ar and N₂ of sputtering gas used when the TiN film of the lower electrode is formed are set to 28 sccm and 40 sccm, respectively. Namely, a partial pressure ratio of nitrogen gas is about 59%.

The measurement results represented by symbols P and Q illustrated in FIG. 8A are for samples P and Q, respectively. It can be seen that as a partial pressure of nitrogen gas when the TiN film of the lower electrode is formed is made low, the breakdown voltage becomes high. This is because a surface roughness of the TiN film of the lower electrode is reduced.

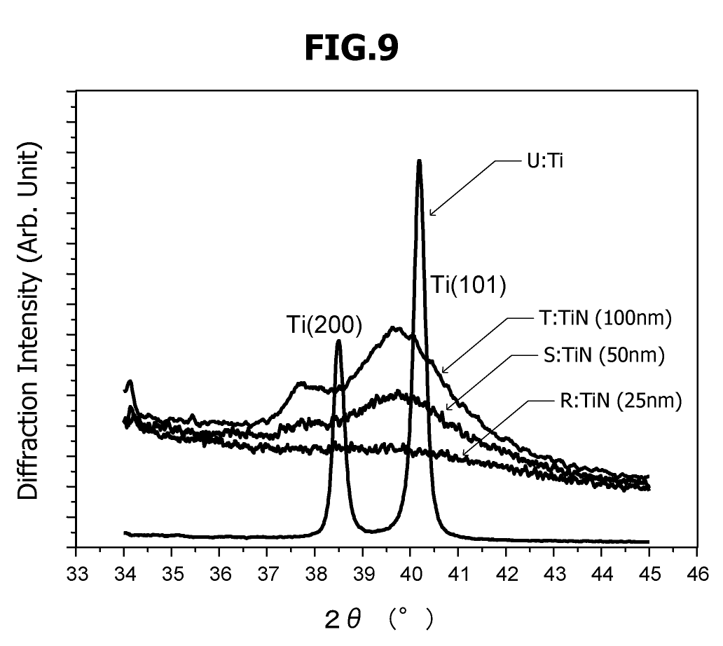

FIG. 9 illustrates X-ray diffraction pattern of three samples R, S and T having different TiN film thicknesses and sample U having a Ti film. The TiN films of samples R, S and T are formed under the conditions that the flow rates of Ar and N₂ of sputtering gas are set to 100 sccm and 20 sccm, respectively. The Ti film of sample U is formed under the condition that the flow rate of Ar of sputtering gas is set to 100 sccm. Thicknesses of the Ti films of samples R, S and T are 25 nm, 50 nm and 100 nm, respectively.

As the TiN film becomes thicker, broad peaks appear near at the peaks caused by the Ti (200) and (101) planes. At a TiN film thickness of 25 nm, peaks are hardly observed. It can be considered from this that at a TiN film thickness of about 25 nm, crystallization progresses hardly and the film is in an amorphous state.

It is preferable to make the TiN film as thin as possible, in order to reduce a surface roughness of the TiN film constituting the surface layer of the lower electrode. As described with reference to FIGS. 7A to 7D, a sufficient lifetime is ensured by making the TiN film amorphous or microcrystalline even if the thickness of the TiN film is 50 nm. It can therefore be considered that a sufficient lifetime is ensured in a range of a TiN film thickness equal to or thinner than 50 nm.

The second lower electrode 22a of TiN illustrated in FIG. 1G serves as an etching stopper layer when the via hole 46h penetrating the dielectric film 23a is formed. The first lower electrode 21a of Al does not have sufficient etching resistance characteristics under the etching conditions for the dielectric film 23a. Therefore, if the second lower electrode 22a is too thin, it is difficult to stop etching when the lower electrode 21a or 22a is exposed on the bottom of the via hole. In order to stop etching for the via hole at the second lower electrode 22a with good reproductivity, it is preferable to set a thickness of the second lower electrode 22a to 20 nm or thicker.

Further, as a nitrogen concentration in the TiN film lowers and the compositions of the TiN film are near those of pure Ti, the etching resistance characteristics lower under the etching conditions for forming a via hole through the dielectric film 23a. It has been confirmed that the TiN film having a nitrogen concentration of 8 atm % illustrated in FIG. 6 has sufficient etching resistance characteristics. From the viewpoint of the etching resistance characteristics, it is preferable to set a nitrogen concentration in the TiN film to 8 atm % or higher.

Furthermore, the second lower electrode 22a illustrated in FIG. 1H serves also as a barrier film for preventing mutual diffusion of Al atoms in the first lower electrode 21a and W atoms in the conductive plug 46.

In the embodiment described above, as the surface layer (second lower electrode 22a) of the lower electrode of a MIM capacitor, a TiN film is adopted which has an intermediate property between pure Ti, and TiN having a stoichiometric composition ratio. A surface roughness of the lower electrode can therefore be reduced more than adopting TiN having a stoichiometric composition ratio. Further, sufficient etching resistance characteristics and barrier characteristics are ensured more than adopting Ti as the lower electrode.

In the embodiment described above, it is not necessary to deposit on the TiN film of the lower electrode, another film made of different material for planarizing. It is also unnecessary to perform CMP, etch-back or the like for surface planarization.

In the embodiment described above, although metal containing Ti and N is used for the second lower electrode 22a, other amorphous or microcrystalline metals may also be used. By using amorphous or microcrystalline metal, a surface roughness can be reduced more than using polycrytalline metal. In the embodiment described above, Al is used for the first lower electrode 21a. The first lower electrode 21a has a function of lowering resistance of the lower electrode of the MIM capacitor 25. Therefore, conductive material having a lower resistivity than that of the second lower electrode 22a other than Al may be used for the first lower electrode 21a.

TiN of the upper electrode 24a is not required to be amorphous or microcrystalline, but polycrystal having a columnar structure may be used. Conductive material other than TiN may be used for the upper electrode 24a. Dielectric material other than SiN may be used for the dielectric film 23a.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relates to a showing of the superiority and inferiority of the invention. Although the embodiment of the present inventions have been described in detail, it should be understood that the various changes, substitutions, and alterations could be made hereto without departing from the spirit and scope of the invention.

What is claimed is:

1. A semiconductor device comprising:
a semiconductor substrate; and
a thin film capacitor disposed over the semiconductor substrate, the thin film capacitor comprising a lower electrode at least a surface layer of which is made of amorphous or microcrystalline metal, a dielectric film disposed over the lower electrode, and an upper electrode disposed over the dielectric film.

2. The semiconductor device according to claim 1, wherein the lower electrode comprised a first lower electrode on a side of the semiconductor substrate and a second lower electrode in contact with the dielectric film, the second lower electrode is made of metal comprising Ti and N and has a thickness equal to or thinner than 50 nm, and the first lower electrode is made of material having a resistivity lower than the second lower electrode.

3. The semiconductor device according to claim 2, wherein a nitrogen concentration of the second lower electrode is in a range between 8 atm % and 35 atm %.

4. A manufacture method for a thin film capacitor comprising:
forming a first lower electrode film made of conductive material over a semiconductor substrate;
forming a second lower electrode film made of metal comprising Ti and N over the first lower electrode film under a condition that the second lower electrode film is amorphous or microcrystalline;
forming a dielectric film over the second lower electrode film; and
forming an upper electrode film made of conductive material over the dielectric film.

5. The manufacture method for a thin film capacitor according to claim 4, wherein the second lower electrode film is formed by reactive sputtering using a Ti target, and Ar and nitrogen as sputtering gas and setting a ratio of a flow rate of nitrogen gas to a total flow rate of the sputtering gas in a range equal to or smaller than 30%.

6. The manufacture method for a thin film capacitor according to claim 4, wherein the second lower electrode film is formed to a thickness equal to or thinner than 50 nm.

7. The manufacture method for a thin film capacitor according to claim 5, wherein the second lower electrode film is formed to a thickness equal to or thinner than 50 nm.
